(19) United States
(12) Patent Application Publication
(10) Pub. No.: US 2011/0110104 A1
(43) Pub. Date: May 12, 2011

(54) OPTICAL PLATE AND METHOD OF MANUFACTURING THE SAME

(75) Inventors: Seung-Mo Kim, Yongin-si (KR); Dong-Yeol Yeom, Cheonan-si (KR); Seunghwan Chung, Asan-si (KR); Insun Hwang, Suwon-si (KR); Donghoon Kim, Suwon-si (KR); Kang-Woo Lee, Suwon-si (KR)

(73) Assignee: SAMSUNG ELECTRONICS CO., LTD, Suwon-si (KR)

(21) Appl. No.: 12/822,356

(22) Filed: Jun. 24, 2010

(30) Foreign Application Priority Data
Nov. 10, 2009 (KR) 10-2009-0108236

(51) Int. Cl. F21V 7/00; B32B 38/00; G03F 7/20; C23C 14/34

(52) U.S. Cl. 362/341; 156/242; 156/244.11; 430/321; 204/192.26

(57) ABSTRACT

An optical plate includes a first optical sheet, a reflective layer, and a second optical sheet. The first optical sheet includes first patterns protruding from a front surface. At least a portion of the first patterns includes a top surface parallel to the front surface. The reflective layer is provided on the top surface. A second optical sheet includes a rear surface making contact with the reflective layer. The optical plate is manufactured by forming the first optical sheet including the first patterns protruding from the front surface, forming the second optical sheet including the reflective layer and an adhesion layer, and bonding the first optical sheet with the second optical sheet such that at least the portion of the first patterns makes contact with the reflective layer.

This application claims priority to Korean Patent Application No. 2009-108236 filed on Nov. 10, 2009, and all the benefits accruing therefrom under 35 U.S.C. §119, the contents of which are herein incorporated by reference in their entirety.

### BACKGROUND OF THE INVENTION

1. Field of the Invention

The invention relates to an optical plate and a method of manufacturing the same. More particularly, the invention relates to an optical plate capable of improving brightness and a method of manufacturing the optical plate.

2. Description of the Related Art

A liquid crystal display (“LCD”) includes a liquid crystal panel to display images. However, since the LCD is a non-emissive device, the LCD requires an additional light source. Accordingly, the LCD includes a backlight unit to supply light to the liquid crystal panel.

The backlight unit includes a light source to emit light and an optical member to transmit the light emitted from the light source. The optical member converts the light emitted from the light source to enhance the brightness of light supplied to the liquid crystal panel.

Development of the LCD has tended toward slimness. In addition, since lower power consumption and lower cost have been required in the LCD, a backlight unit has been developed to provide high brightness with a small number of light sources.

### BRIEF SUMMARY OF THE INVENTION

Embodiments of the invention provide an optical plate capable of improving brightness of light emitted therefrom.

Embodiments of the invention provide a method of manufacturing the optical plate.

According to embodiments, the optical plate includes a first optical sheet, a reflective layer, and a second optical sheet. The first optical sheet includes first patterns protruding from a first front surface. At least a portion of the first patterns includes a top surface substantially parallel to the first front surface. The reflective layer is provided on the top surface. The second optical sheet includes a rear surface making contact with the reflective layer.

Each first pattern may be a prism mountain including the top surface substantially parallel to the first front surface, and the prism mountain may extend in a first direction.

The first patterns includes first sub-patterns having a first height from the first front surface and second sub-patterns having a second height, which is greater than the first height, from the first front surface, and the reflective layer may be provided on the second sub-patterns. Each first sub-pattern may be a prism mountain extending in one direction, and may be one of a pyramid pattern, a lenticular pattern, and a semi-oval sphere pattern. Each second sub-pattern may be one of a cylinder shape, a poly-prism shape, an elliptic cylinder shape, a truncated conical shape, and a truncated poly-pyramidal shape, and a top surface of each second sub-pattern may be substantially parallel to the first front surface.

The second optical sheet may include second patterns protruding from a second front surface, and each second pattern may be a prism mountain extending in a second direction crossing a first direction.

The second optical sheet is provided at a rear surface thereof with an adhesion layer to bond the first optical sheet with the second optical sheet.

According to embodiments, a method of manufacturing the optical plate is provided as follows. A first optical sheet including first patterns protruded from a front surface is formed. A second optical sheet is formed. A reflective layer is formed on a portion of the second optical sheet. An adhesion layer is formed on the second optical sheet. The first optical sheet is bonded to the second optical sheet such that at least a portion of the first patterns makes contact with the reflective layer.

In order to form the first optical sheet, first sub-patterns having a first height are formed on a base sheet, and second sub-patterns having a second height greater than the first height are formed on the base sheet. The first and second sub-patterns may be formed through a single process. The second sub-patterns may be formed through a photolithography process or a sputtering process using a mask.

As described above, the reflective layer is interposed between first and second optical sheets, thereby improving efficiency of light provided to a display panel of a display apparatus. In addition, since the top surface of each first pattern is sufficiently wide while maintaining high light efficiency, the first and second optical sheets may be stably bonded with each other. Accordingly, delamination between the first and second optical sheets may be reduced or effectively prevented.

In addition, the optical plate may be simply manufactured, so that the manufacturing time and cost may be reduced.

### BRIEF DESCRIPTION OF THE DRAWINGS

The above and other advantages of the invention will become readily apparent by reference to the following detailed description when considered in conjunction with the accompanying drawings wherein:

FIG. 1 is an exploded perspective view showing an exemplary embodiment of a display apparatus including an optical plate according to the invention;

FIG. 2 is a perspective view partially showing an exemplary embodiment of the optical plate according to the invention;

FIG. 3 is a cross-sectional view taken along line III to III′ of FIG. 2;

FIG. 4 is a perspective view partially showing another exemplary embodiment of the optical plate according to the invention;

FIG. 5 is a cross-sectional view taken along line V to V′ of FIG. 4;

FIG. 6 is a perspective view partially showing another exemplary embodiment of the optical plate according to the invention; and

FIGS. 7A to 7D are cross-sectional views showing an exemplary embodiment of a method of manufacturing the optical plate shown in FIGS. 2 and 3 according to the invention.

### DETAILED DESCRIPTION OF THE INVENTION

Hereinafter, an optical plate according to embodiments of the invention will be described with reference to accompanying drawings. For the purpose of explanation, a display apparatus employing the optical plate according to an embodiment of the invention will be primarily described, and then, embodiments of the optical plate will be described in detail. Hereinafter, a liquid crystal display will be described as an exemplary embodiment of the display apparatus.

The invention is not limited to the following embodiments but includes various applications and modifications. The following embodiments are provided to clarify the technical spirit disclosed in the invention and to sufficiently transmit the technical spirit of the invention to the one having mean knowledge and skill in this field. Therefore, the scope of the invention should not be limited to the following embodiments. In addition, the size of the layers and regions of the attached drawings along with the following embodiments are simplified or exaggerated for precise explanation or emphasis and the same reference numeral represents the same component. For the purpose of explanation, a first portion of a display panel where an image is displayed will be referred to as a ‘top’, ‘front’, or ‘front direction’, and a second portion of the display panel opposite to the first portion will be referred to as a ‘bottom’, ‘rear’, or ‘rear direction’.

It will be understood that when an element or layer is referred to as being “on” or “coupled to” another element or layer, the element or layer can be directly on or coupled to another element or layer or intervening elements or layers. In contrast, when an element is referred to as being “directly on” or “directly coupled to” another element or layer, there are no intervening elements or layers present. As used herein, the term “and/or” includes any and all combinations of one or more of the associated listed items.

It will be understood that, although the terms first, second, third, etc., may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the invention.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments of the invention are described herein with reference to cross-section illustrations that are schematic illustrations of idealized embodiments (and intermediate structures) of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

All methods described herein can be performed in a suitable order unless otherwise indicated herein or otherwise clearly contradicted by context. The use of any and all examples, or exemplary language (e.g., “such as”), is intended merely to better illustrate the invention and does not pose a limitation on the scope of the invention unless otherwise claimed. No language in the specification should be construed as indicating any non-claimed element as essential to the practice of the invention as used herein.

Hereinafter, the invention will be described in detail with reference to the accompanying drawings.

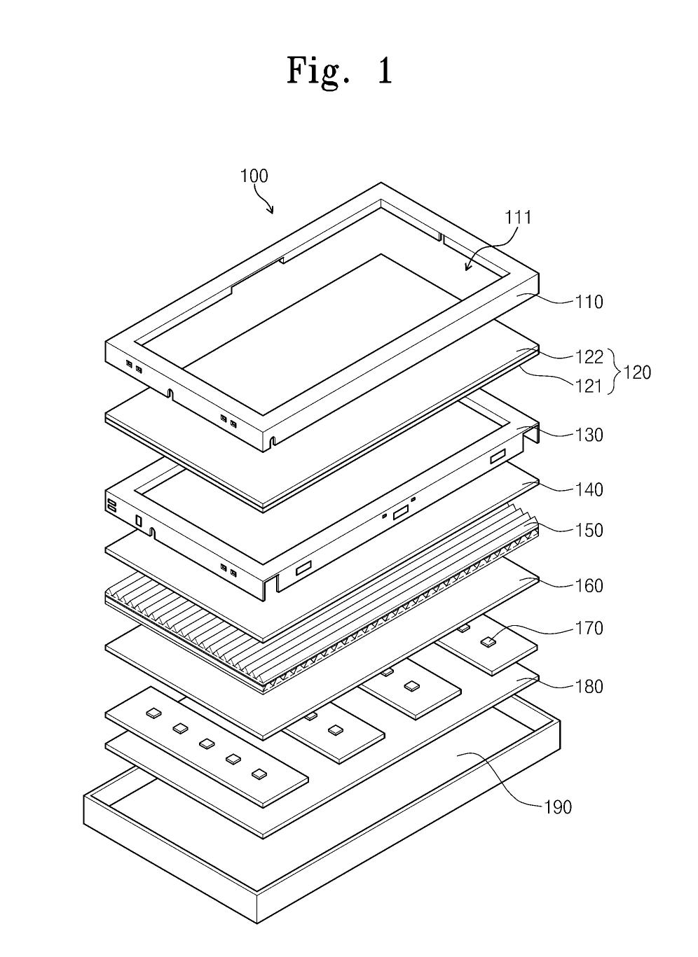

FIG. 1 is an exploded perspective view showing an exemplary embodiment of a display apparatus 100 including the optical plate according to the invention.

Referring to FIG. 1, the display apparatus 100 includes a display panel 120 to display images on a front surface thereof, e.g., on a viewing side of the display apparatus 100.

A mold frame 130 is provided at an edge of the display panel 120 to support the display panel 120. Optical members 140, 150, and 160 are provided below the mold frame 130, that is, at the rear of the display panel 120. A plurality of a light source 170 is provided at a rear and/or a side surface of the optical members 140, 150, and 160, to supply light to the display panel 120 through the optical members 140, 150, and 160.

An element to supply the light to the display panel 120 as described above is called a backlight unit, and the backlight unit collectively includes the plurality of the light source 170 and the optical members 140, 150, and 160. The illustrated exemplary embodiment employs a direct-type backlight unit in which the plurality of the light source 170 is placed at the rear of the optical members 140, 150, and 160.

The plurality of the light source 170 are provided at the rear thereof with a reflective sheet 180 to reflect light, which leaks without supplying toward the display panel 120, to change the path of the light to the display panel 120.

The reflective sheet 180 is provided at the rear thereof with a lower cover 190 receiving therein the display panel 120, the plurality of the light source 170, the reflective sheet 180, and so on. The display panel 120 is provided at the front thereof with an upper cover 110 coupled with the lower cover 190. The upper cover 110 supports an edge of the front surface of the display panel 120. The upper cover 110 is provided with a display window disposed extending completely therethrough 111, to expose a display region of the display panel 120 to the viewing side of the display apparatus 100.

The display panel 120 may include various display panels, such as a liquid crystal display panel and an electrophoretic display panel, sufficient to display the images. In the illustrated exemplary embodiment, the liquid crystal display panel will be representatively described.

The display panel 120 having a rectangular plate-like shape in a plan view of the display apparatus 100, and includes longer (e.g., longitudinal) and shorter (e.g., transverse) sides. The display panel 120 includes a first substrate 121, a second substrate 122 opposite to the first substrate 121, and liquid crystal (not shown) interposed between the first and second substrates 121 and 122. The display panel 120 drives the liquid crystal to display the images on the front surface thereof. The first substrate 121 may include thin film transistors, and the second substrate 122 may include color filters.

The mold frame 130 is provided along the edge of the display panel 120. The mold frame 130 may substantially have a rectangular frame shape in the plan view of the display apparatus 100, that is, having longer and shorter sides with an open area framed by the sides. The mold frame 130 is coupled with the lower cover 190 to receive therein the optical members 140, 150, and 160, the plurality of the light source 170, and the reflective sheet 180. A single unitary indivisible mold frame 130 may be employed in the display apparatus 100 as shown in FIG. 1. Alternatively, a plurality of mold frames 130 or a plurality of individual discrete members may be assembled together to form the mold frame 130 if necessary.

The optical members 140, 150, and 160 control the light generated from the plurality of the light source 170. The optical members 140, 150, and 160 include, but are not limited to, the protective sheet 140, the optical plate 150, and the diffusion plate 160, sequentially stacked on each other.

The diffusion plate 160 diffuses the light generated from the plurality of the light source 170.

The optical plate 150 concentrates the light diffused from the diffusion plate 160, perpendicularly to a plane of the display panel 130. Most light that has passed through the optical plate 150 is incident onto the display panel 120 perpendicularly to the display panel 120.

The protective sheet 140 is placed on a front of the optical plate 150. The protective sheet 140 protects the optical plate 150 from being scratched.

In an alternative exemplary embodiment, the protective sheet 140 and/or the diffusion plate 160 may be omitted. In addition, another optical sheet such as a brightness enhancement film (“BEF”) may be further included. Description about the optical plate 150 will be made later.

The optical members 140, 150, and 160 may be collectively formed by using a plurality of a sheet. In an exemplary embodiment, the optical members 140, 150, and 150 may be formed by folding two or three sheets.

The optical members 140, 150, and 160 are provided at the rear thereof with the plurality of the light source 170 to supply light to the display panel 120. Although the plurality of the light source 170 includes light emitting diodes as shown in FIG. 1, the light source 170 may include a cold cathode fluorescent lamp, an external electrode fluorescent lamp, or a hot cathode fluorescent lamp.

The reflective sheet 180 is provided below the light sources 170, e.g., towards a rear of the display apparatus 100. The reflective sheet 180 reflects light towards an upward (e.g. front) direction that has been incident in a downward direction from the light sources 170 towards the rear of the display apparatus 100.

In the display apparatus 100 having the above structure, the light generated from the plurality of the light source 170 is supplied to the display panel 120 after the light is transmitted through the optical members 140, 150, and 160. The display panel 120 receives the light to display the images on the front surface thereof.

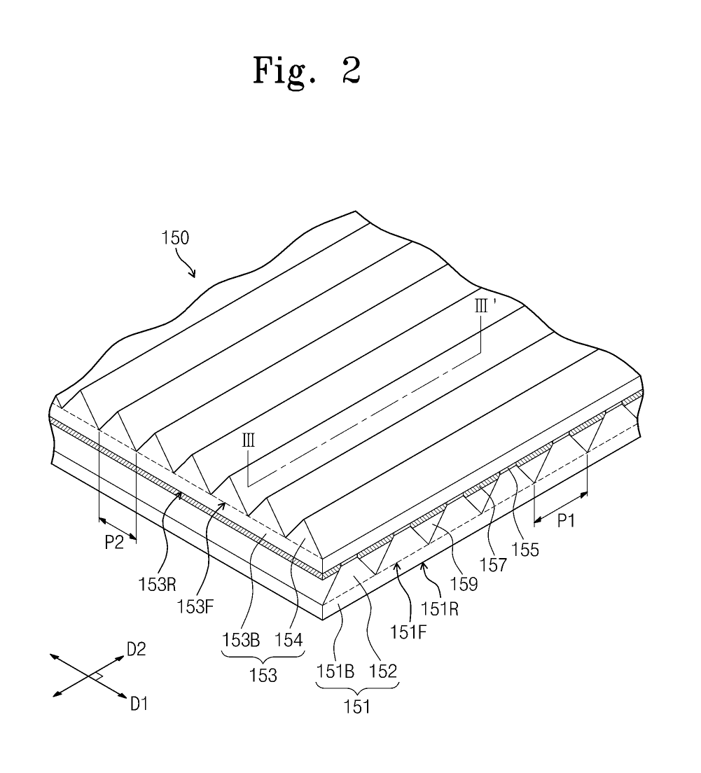

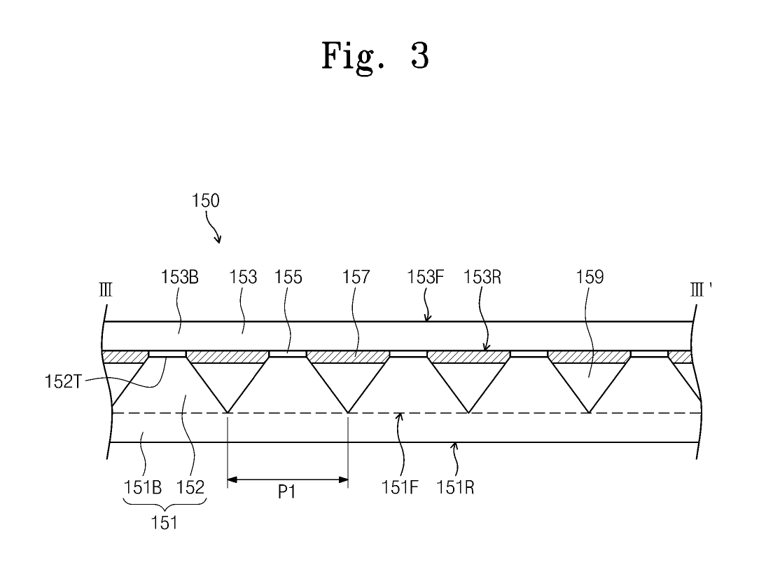

FIG. 2 is a perspective view showing an exemplary embodiment of the optical plate 150 according to the invention, and FIG. 3 is a cross-sectional view taken along line III-III′ of FIG. 2.

Referring to FIGS. 1 to 3, the optical plate 150 according to the illustrated embodiment of the invention collectively includes a first optical sheet 151, a second optical sheet 153, and a reflective layer 155 interposed between the first and second optical sheets 151 and 153.

The first optical sheet 151 includes a first base 151B, and a plurality of a first pattern 152 disposed on an upper surface of the first base 151B. The plurality of the first pattern 152 may be integrated with the first base 151B, such that the first optical sheet 151 is a single unitary indivisible member, and the plurality of the first pattern 152 is not separable from the first base 151B.

The first base 151B has a rectangular plate-like shape in a plan view of the optical plate 150 and includes a front surface 151F indicated by the dotted line in FIGS. 2 and 3, and a rear surface 151R opposite to the front surface 151F. The rear surface 151R of the first base 151B may define a rearmost or lowermost surface of the optical plate 150.

The plurality of the first pattern 152 is provided directly on the front surface 151F of the first base 151B. A portion of the first pattern 152 that is coplanar with the front surface 151F of the first base 151B is considered a base of the first pattern 152. The plurality of the first pattern 152 protrudes toward the display panel 120 from the front surface 151F, e.g., from the base of the first pattern 152. Each first pattern 152 longitudinally extends in a first direction D1 to form a prism mountain. The plurality of the first pattern 152 is arranged in a second direction D2.

An upper portion of each first pattern 152 is cut away such that the first pattern 152 has a top surface 152T (FIG. 3) substantially parallel to the front surface 151F, to easily adhere to the second optical sheet 153. Although each first pattern 152 is designated as a prism mountain for the purpose of explanation, the cross section of each first pattern 152 taken perpendicular to the first direction D1 does not have a triangle shape, but substantially has a trapezoid shape.

The first direction D1 may be parallel to one of longer and shorter sides of the rectangle shaped optical plate 150, but the first direction D1 should not be limited thereto or thereby. In one exemplary embodiment, the first direction D1 may be inclined with respect to one of the longer and shorter sides of the rectangle shaped optical plate 150.

A pitch P1 of each first pattern 152, that is, a length of a side (e.g., the base) of the first pattern 152 in contact with the first base 151B, may be in the range of about 50 micrometers (μm) to about 100 micrometers (μm).

The plurality of the first pattern 152 is used to concentrate light, which has passed through the first optical sheet 151, in a front direction of the optical plate 150. Since the prism mountain of the first pattern 152 longitudinally extends in the first direction D1, high light concentration efficiency can be represented perpendicularly to the first direction D1.

The second optical sheet 153 includes a second base 153B and a plurality of a second pattern 154 disposed directly on an upper surface of the second base 153B. The plurality of the second pattern 154 may be integrated with the second base 153B, such that the second optical sheet 153 is a single unitary indivisible member, and the plurality of the second pattern 154 is not separable from the second base 153B.

The second base 153B has the shape of a plate in the plan view of the optical plate 150 and includes a front surface 153F indicated by the dotted line in FIG. 2, and a rear surface 153R opposite to the front surface 153F.

The plurality of the second pattern 154 is provided directly on the front surface 153F of the second base 153B. A portion of the second pattern 154 that is coplanar with the front surface 153F of the second base 153B is considered a base of the second pattern 154. The plurality of the second pattern 154 protrude toward the display panel 120 from the front surface 153F. Each second pattern 154 longitudinally extends in a second direction D2 to form a prism mountain. The plurality of the second pattern 154 is arranged in the first direction D1. Different from the first patterns 152, an upper portion of the second pattern 154 is not cut away, and sides of the second pattern 154 continue to meet at a common point, e.g., a peak.

The second direction D2 crosses the first direction D1. Although the first and second directions D1 and D2 cross each other while forming a right angle according to the illustrated embodiment of the invention, the first and second directions D1 and D2 should not be limited thereto or thereby. According to another exemplary embodiment of the invention, the first and second directions D1 and D2 cross each other while forming various angles.

A pitch P2 of each second pattern 154, that is, a length of a side (e.g., the base) of each prism mountain in contact with the second base 153B may be in the range of about 50 μm to about 100 μm. The pitch P1 of the first pattern 152 is greater than the pitch P2 of the second pattern 154 such that light concentration efficiency can be increased.

The plurality of the second pattern 154 is used to concentrate light that has passed through the second optical sheet 153. Since the prism mountain of the second pattern 154 longitudinally extends in the second direction D2, light is concentrated in a direction perpendicular to the second direction D2, that is, the first direction D1. Accordingly, since the light output from the plurality of the light source 170 is concentrated in both the first and second directions D1 and D2 which are perpendicular to each other, through the first and second optical sheets 151 and 153, most light incident onto the optical plate 150 is supplied to the display panel 120.

In an exemplary embodiment, the first and second optical sheets 151 and 153 may include polymer resin, including but not limited to, polyethyleneterephthalate.

The reflective layer 155 and an adhesion layer 157 are both interposed between the first and second optical sheets 151 and 153. Edges of the adhesion layer 157 extend to edges of the first optical sheet 151 and/or the second optical sheet 153, as shown in FIG. 2. Portions of the adhesion layer 157 are disposed between adjacent first patterns 152.

The reflective layer 155 is interposed directly between the top surface 152T of each first pattern 152 and the rear surface 153R of the second optical sheet 153. The reflective layer 155 may include a material capable of reflecting light. In one exemplary embodiment, the reflective layer 155 may include a metal-contained material, such as a metal oxide. The metal oxide may include Titanium Dioxide (TiO₂). The reflective layer 155 may include various materials sufficient to reflect light instead metal. In one exemplary embodiment, the reflective layer 155 may include Barium Sulphate (BaSO₄).

The adhesion layer 157 is provided directly on the rear surface 153R of the second optical sheet 153, except for a region in which the reflective layer 155 is disposed. The adhesion layer 157 is used to bond the first optical sheet 151 to the second optical sheet 153.

The adhesion layer 157 may have a thickness of about 0.1 μm to about 50 μm taken in a direction substantially perpendicular to the rear surface 153R of the second optical sheet 153. The adhesion layer 157 may include at least one of acrylic polymer resin, polyester polymer resin, and polycarbonate polymer resin. The adhesion layer 157 may include at least one kind of an organic material or an inorganic material such that the light passing through the adhesion layer 157 is diffused. Although the adhesion layer 157 is not shown between the reflective layer 155 and the top surface 152T of the first patterns 152 in FIGS. 2 and 3, a portion of the adhesion layer 157 may be disposed between the reflective layer 155 and the top surface 152T of the first pattern 152, so that the adhesive strength between the reflective layer 155 and the top surface 152T of the first pattern 152 can be increased.

An air (e.g., buffer) layer area 159 is provided between the adhesion layer 157 and the plurality of the first pattern 152. In the air layer area 159, no material of the first optical sheet 151, the second optical sheet 153, the reflective layer 155 or the adhesion layer 157 is disposed therein.

The optical plate 150 having the above structure can obtain light concentration efficiency superior to that of the typical prism sheet. The optical plate 150 according to the illustrated exemplary embodiment of the invention includes the plurality of the first pattern 152 disposed extended in the first direction D1, and the plurality of the second pattern 154 disposed in the second direction D2, so that the light transmitted from the rear surface of the optical plate 150 to the front surface of the optical plate 150 is concentrated in the front direction of the optical plate 150. The light concentration effect occurs due to the difference with a refractive index of the air layer 159. In other words, according to Snell's law, as the difference in a refractive index between two media is increased, the refractive index of the transmitted light is increased. Since light is refracted at an interfacial surface between air in the air layer 159 and the first optical sheet 151 and the interfacial surface between air and the second optical sheet 153, the optical plate 150 according to the illustrated exemplary embodiment of the invention can represent high light concentration efficiency.

In addition, the reflective layer 155 is provided between the first optical sheet 151 and the second optical sheet 153, thereby increasing the efficiency of the light provided to the display panel 120. In other words, light, which passes through the top surface 152T, of the light transmitted from the rear surface 151R to the front surface 151F is reflected by the reflective layer 155 to return to the rear surface 151R from the front surface 151F. The light that has returned to the rear surface 151R from the front surface 151F is again supplied to the front surface 151F by the reflective sheet 180 of the display apparatus 100. Accordingly, the light can be recycled, so that the efficiency of light provided to the display panel 120 is increased.

In addition, while maintaining high light efficiency, an areal dimension in the plan view of the optical plate 150 of the top surface 152T of the first pattern 152 is wide enough to stably bond the first optical sheet 151 with the second optical sheet 153. Accordingly, delamination between the first optical sheet 151 and the second optical sheet 153 can be reduced. Conventionally, when at least two BEFs are used, the BEFs may be damaged due to abrasion. According to the exemplary embodiments of the invention, since one optical plate 150 is used, the optical plate 150 is not damaged due to abrasion. In addition, a protective layer to protect the conventional BEF can be omitted, so that the manufacturing cost can be reduced.

Table 1 shows the brightness and the contrast ratio in white color when existing diffusion and prism sheets are used, and when the optical plate 150 according to the exemplary embodiment of the invention and an existing diffusion sheet are used. Two existing diffusion sheets and one existing BEF sheet are used in Comparison Example 1. One existing diffusion sheet and two existing BEF sheets are used in Comparison Example 2. One existing diffusion sheet and one optical plate 150 according to the exemplary embodiment of the invention are used in the Experimental Example. In the Experimental Example, the pitch of the first pattern 152 is about 60 μm, and the pitch of the second pattern 154 is about 50 μm.

TABLE 1

| | Comparison | Comparison | Experimental |
|---|---|---|---|
| | Example 1 | Example 2 | Example |
| Brightness (nit) | 500 | 600 | 595 |
| Contrast Ratio | 6500:1 | 7800:1 | 7644:1 |
| Cost (per 40 inch, $) | 8 | 11 | 8 |

As shown in Table 1, the Experimental Example, in which the optical plate 150 according to the exemplary embodiment of the invention is used, represents the brightness and the contrast ratio approximately identical to the Comparison Example 2, in which two existing BEF sheets are used, while representing cost identical to that of the Comparison Example 1 in which two existing diffusion sheets and one BEF sheet are used.

According to the illustrated exemplary embodiment of the invention in FIGS. 2 and 3, although the first pattern 152 have the shape of a prism mountain, the upper portion of which is cut away, the first patterns 152 may have various shapes.

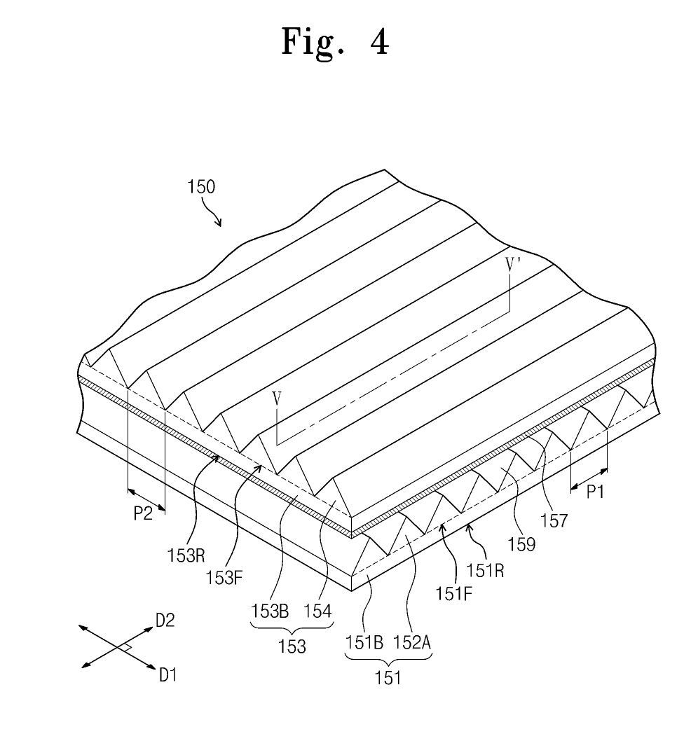

FIG. 4 is a perspective view showing the optical plate 150 according to another exemplary embodiment of the invention, and FIG. 5 is a cross-sectional view taken along line V-V′ of FIG. 4.

The exemplary embodiment of the invention illustrated in FIGS. 4 and 5 will be described while focusing on the difference between the exemplary embodiments in FIGS. 2 and 3, and FIGS. 4 and 5, in order to avoid redundancy. Hereinafter, the same reference numerals denote the same elements.

Referring to FIGS. 4 and 5, the optical plate 150 according to the illustrated exemplary embodiment of the invention includes the first optical sheet 151, the second optical sheet 153, and the reflective layer 155 interposed between the first and second optical sheets 151 and 153.

The first optical sheet 151 includes the first base 151B and the plurality of the first pattern 152 disposed directly on the first base 151B. The first base 151B includes the front surface 151F and the rear surface 151R opposite to the front surface 151F. The plurality of the first pattern 152 includes a plurality of a first sub-pattern 152A and a plurality of a second sub-pattern 152B.

The first and second sub-patterns 152A and 152B are provided directly on the front surface 151F of the first base 151B, and protruded from the front surface 151F toward the display panel 120.

Each first sub-pattern 152A longitudinally extends in the first direction D1 to form a prism mountain.

The second sub-pattern 152B serves as a spacer maintaining a distance in a direction orthogonal to both the first and second directions D1 and D2, between the first and second optical sheets 151 and 153. Accordingly, the first sub-pattern 152A has a first height H1 from the front surface 151F, and the second sub-pattern 152B has a second height H2 from the front surface 151F. The second height H2 is greater than the first height H1. In a plan view of the optical plate 150, the second sub-pattern 152B overlaps adjacent first sub-patterns 152A.

Each second sub-pattern 152B includes the top surface 152T parallel to the front surface 151F to easily adhere to the second optical sheet 153. Although the top surface 152T of the second sub-pattern 152B is flat, the second sub-patterns 152B may have roughness of about 1 μm or more in order to increase reflectivity. The second sub-pattern 152B may have various shapes, such as a cylinder shape, a poly-prism shape, an elliptic cylinder shape, a truncated con shape, and a truncated poly-pyramid shape, having a predetermined height to maintain the distance between the first and second optical sheets 151 and 153.

Since the second height H2 is greater than the first height H1, the plurality of the first sub-pattern 152A is spaced apart from the second optical sheet 153, which is supported by the plurality of the second sub-pattern 152B, with a predetermined distance.

An average of a distance D between the first sub-pattern 152A of the first optical sheet 151 and the second optical sheet 153 is greater than a wavelength of light passing through the first and second optical sheets 151 and 153. Since a light source used in the LCD emits light having a wavelength of about 250 nanometers (nm) to about 800 (nm) the distance D is greater than the wavelength to maximize the refraction of light between the air layer 159 and the first and second optical sheets 151 and 153. In addition, since the height of individual members of the plurality of the first pattern 152 of the first optical sheet 151 is substantially irregular, the distance D between the first sub-pattern 152A and the second optical sheet 153 may be about 2 (μm) based on the bending degree of the first optical sheet 151.

The plurality of the second sub-pattern 152B may be disposed directly on the front surface 151F of the first optical sheet 151 at a uniform interval or an irregular interval in the second direction D2. The plurality of the second sub-pattern 152B is required only to maintain the distance between the first optical sheet 151 and the second optical sheet 153. Accordingly, only a minimum number of the second sub-pattern 152B sufficient to maintain the distance between the first and second optical sheets 151 and 153 are disposed to maximize the light concentration effect by the plurality of the first sub-pattern 152A. In one exemplary embodiment, the first optical sheet 151 may be formed in such a manner that at least one second sub-pattern 152B is disposed in a planar view rectangular area having a width of about 10 millimeters (mm) and a length of about 10 millimeters (mm).

The first and second sub-patterns 152A and 152B may be integrally formed with the first base 151B such that the first and second sub-patterns 152A and 152B and the first base sheet 151B are continuous and not separable from each other, and collectively form a single unitary indivisible first optical sheet 151. Alternatively, the first and second sub-patterns 152A and 152B may be separable or distinct from the first base 151B. In one exemplary embodiment, the first base 151B may be integrally formed with the plurality of the first sub-patterns 152A, and the plurality of the second sub-pattern 152B may include a material different from that of the first base 151B and the plurality of the first sub-pattern 152A.

The reflective layer 155 is interposed directly between the top surface 152T of each second sub-pattern 152B and the rear surface 153R of the second optical sheet 153. The adhesion layer 157 is provided on the rear surface 153R of the second optical sheet 153, except for a region in which the reflective layer 155 is disposed.

In addition, the reflective layer 155 is provided directly between the first optical sheet 151 and the second optical sheet 153, thereby increasing the efficiency of light provided to the display panel 120. In other words, the light, which passes through the top surface 152T, of the light transmitted from the rear surface 151R to the front surface 151F is reflected by the reflective layer 155. The light that has returned to the rear surface 151R from the front surface 151F is again supplied to the front surface 151F by the reflective sheet 180 of the display apparatus 100. Accordingly, the light can be recycled, so that the efficiency of light provided to the display panel 120 is increased.

According to the exemplary embodiment of the invention illustrated in FIGS. 4 and 5, since the distance between the first and second optical sheets 151 and 153 is maintained by the second sub-pattern 152B, the first sub-pattern 152A may have the shape of a substantially perfect prism mountain, where there is no flat top surface as 152T of FIG. 3. Accordingly, the light concentration efficiency of the first sub-pattern 152A in FIGS. 4 and 5, is higher than that of the first pattern 152 according to the exemplary embodiment shown in FIGS. 2 and 3.

Table 2 shows the relative value of brightness in white color when existing diffusion and BEF sheets are used, and when the optical plate 150 according to the exemplary embodiment of the invention in FIGS. 4 and 5 and an existing diffusion sheet are used. One existing diffusion sheet and two existing BEF sheets are used in a Comparison Example. One existing diffusion sheet and one optical plate 150 according to the exemplary embodiment of the invention in FIGS. 4 and 5 are used in an Experimental Example. In the Experimental Example, the pitch of each first sub-pattern 152A is about 60 μm, and the pitch of each second pattern 154 is about 50 μm. In the Comparison Example, the brightness represents 100%.

TABLE 2

| | Comparison Example | Experimental Example |
|---|---|---|
| Center Brightness (nit) | 186 (100%) | 184.3 (99%) |

As shown in Table 2, the Experimental Example, in which the optical plate 150 according to the exemplary embodiment of the invention in FIGS. 4 and 5 is used, represents the brightness identical (e.g., 99%) to that of the Comparison Example, in which two existing BEF sheets are used.

According to the illustrated exemplary embodiment of the invention in FIGS. 4 and 5, although the first sub-pattern 152A and the second pattern 154 have the shape of a prism mountain, the first sub-pattern 152A and the second pattern 154 may have various shapes.

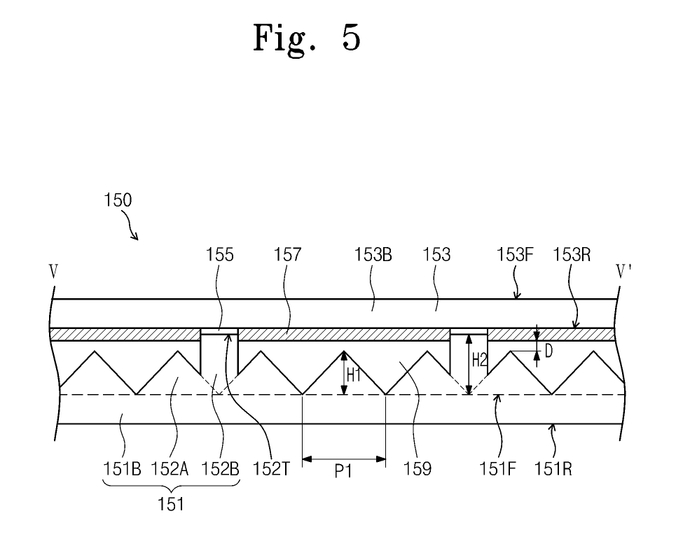

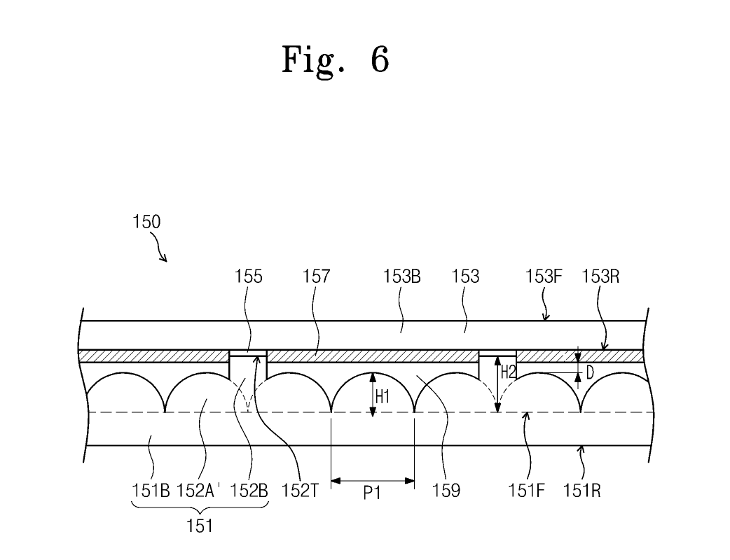

FIG. 6 is a cross-sectional view showing the optical plate 150 according to another exemplary embodiment of the invention.

As shown in FIG. 6, the optical plate 150 according to the illustrated exemplary embodiment of the invention includes the first sub-pattern 152A′ having a lenticular shape.

As described above, patterns on the first and second optical sheets 151 and 153 may have various shapes in order to enhance the light concentration efficiency. In one exemplary embodiment, although not shown in figures, the first sub-pattern 152A may have a hemi-sphere shape, a hemi-oval sphere shape, or a pyramid shape instead of the lenticular shape.

Although not shown figures, each of the plurality of the second pattern 154 disposed on the second optical sheet 153 may have a lenticular shape, a hemi-sphere shape, a hemi-oval sphere shape, or a pyramid shape. Each of the plurality of the first pattern 152 according to the exemplary embodiment in FIGS. 2 and 3 may have a truncated lenticular shape, a truncated hemispherical shape, a truncated hemi-oval spherical shape, or a truncated pyramidal shape instead of a truncated prism mountain shape.

As described above, various patterns are disposed on the first and second optical sheets 151 and 153 to variously adjust the light concentration degree of the optical plate 150 according to the invention.

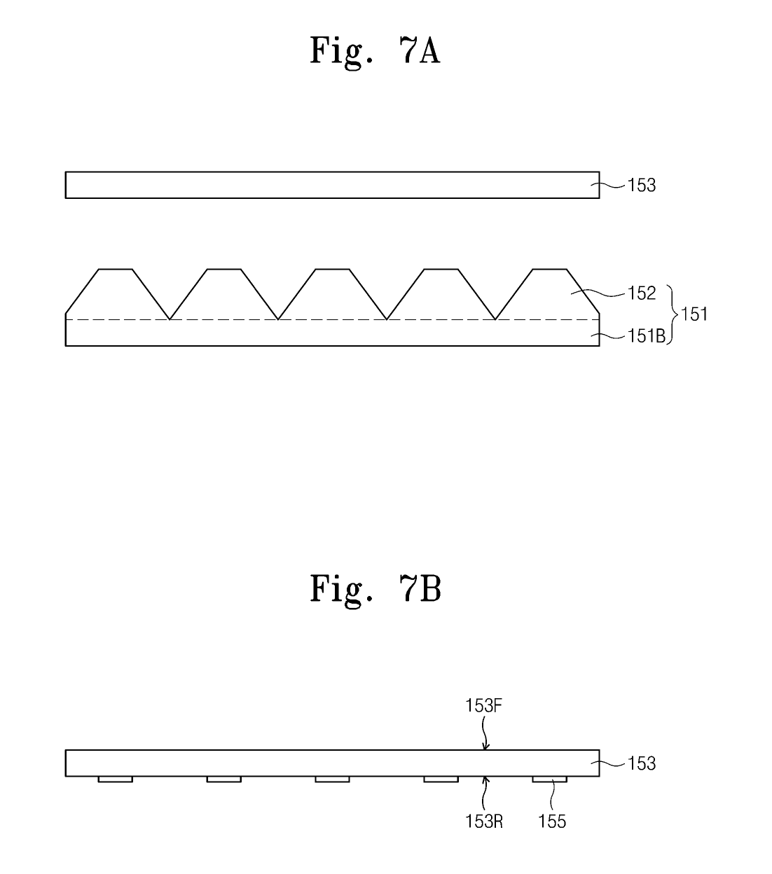

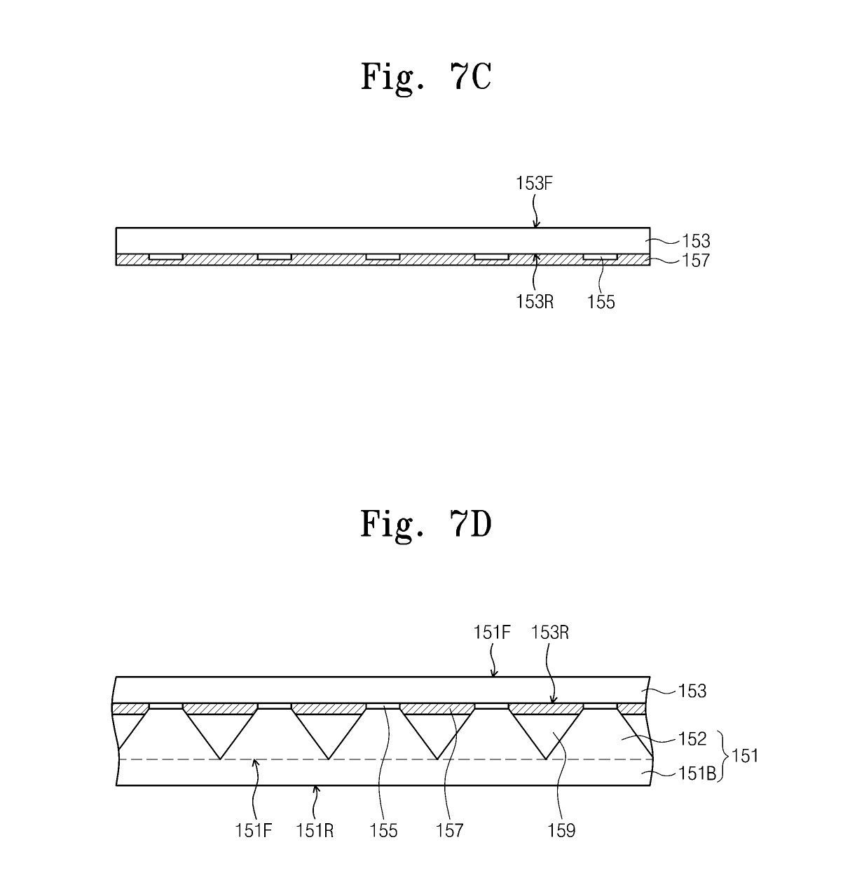

The invention provides a method of manufacturing the optical plate 150 according to an exemplary embodiment. FIGS. 7A to 7D are cross-sectional views showing the method of manufacturing the optical plate 150 according to the exemplary embodiment of the invention shown in FIGS. 2 and 3. Hereinafter, the method of manufacturing the optical plate 150 according to the exemplary embodiment will be described with reference to FIGS. 2 and 3, and FIGS. 7A to 7D.

In order to manufacture the optical plate 150 according to the exemplary embodiment of the invention shown in FIGS. 2 and 3, the first optical sheet 151 including the plurality of the first pattern 152 protruding from the front surface 151F of the first base 151B, and the second optical sheet 153 including the plurality of the second pattern 154, are formed separate from each other, as shown in FIG. 7A.

The plurality of the first pattern 152 of the first optical sheet 151 may be formed through an extrusion scheme or a soft molding scheme.

When the plurality of the first pattern 152 is formed through the extrusion scheme, a master roll (not shown) is prepared to transfer the first pattern 152. The master roll is provided on the surface thereof with patterns inverse to the first pattern 152. The master roll is pressed against a material of the first optical sheet 151, for example, melted polymer resin while rolling the surface of the master roll. Accordingly, the inverse patterns are transferred on the material of the first optical sheet 151. Then, the material of the first optical sheet 151 is cured, so that the plurality of the first pattern 152 can be formed on the surface of the first optical sheet 151.

The master roll is prepared in the form of a cylindrical roller. The surface of the cylindrical roller is peeled off in an axial direction by using a diamond bit, so that a truncated prism mountain pattern can be formed on the surface of the cylindrical roller.

When the plurality of the first pattern 152 is formed through the soft molding scheme, a master mold (not shown) having a pattern inverse to a pattern to be formed is prepared. Then, the master mold having the inverse pattern is pressed against the material of the first optical sheet 151. Accordingly, the inverse pattern is transferred onto the material of the first optical sheet 151, and the material of the first optical sheet 151 is cured, so that the plurality of the first pattern 152 can be formed on the surface of the first optical sheet 151.

Similarly to the first optical sheet 151, the plurality of the second pattern 154 is formed on the front surface 153F of the second optical sheet 153 through the extrusion scheme or the soft molding scheme.

Thereafter, as shown in FIG. 7B, the reflective layer 155 is formed at a portion of the rear surface 153R of the second optical sheet 153. The portion of the rear surface 153R on which the reflective layer 155 is formed makes contact with the top surface 152T of the plurality of the first pattern 152 formed on the separate first optical sheet 151 in the following process.

The reflective layer 155 may be formed by directly printing a reflective material on the rear surface 153R of the second optical sheet 153. Although not shown in figures, the reflective layer 155 may be formed by coating a reflective material on a protrusion (not shown) through a printing scheme after the protrusion is formed at the portion of the rear surface 153R of the second optical sheet 153.

As shown in FIG. 7C, the adhesion layer 157 is formed on the entire portion of the rear surface 153R of the second optical sheet 153 having the reflective layer 155. The adhesion layer 157 may be formed by coating melted polymer resin or semi-cured polymer resin. The melted polymer resin is pre-cured until the melted polymer resin has become semi-cured. Although the adhesion layer 157 is formed on the entire portion of the rear surface 153R of the second optical sheet 153 as shown in FIG. 7C, the adhesion layer 157 may be formed only on a portion of the rear surface 153R if necessary.

Thereafter, as shown in FIG. 7D, the separately formed first and second optical sheets 151 and 153 are bonded with each other. In this case, after the first optical sheet 151 has been pressed against the second optical sheet 153 such that the top surface 152T of the plurality of the first pattern 152 makes contact with the reflective layer 155, the semi-cured polymer resin is completely cured. Although not shown in figures, a portion of the adhesion layer 157 may remain between the reflective layer 155 and the top surface 152T of the first optical sheet 151.

Accordingly, the optical plate 150 according to the exemplary embodiment of the invention shown in FIGS. 2 and 3 is manufactured by bonding the separately formed first optical sheet 151 with the second optical sheet 153.

Although the illustrated exemplary embodiment has been described in that the plurality of the second pattern 154 is formed before the first and second optical sheets 151 and 153 are bonded with each other, the first optical sheet 151 may be bonded with the second optical sheet 153 having no second patterns 154, and then the second patterns 154 may be subsequently formed on the front surface 153F of the second optical sheet 153, according to another exemplary embodiment of the method.

Hereinafter, the method of manufacturing the optical plate 150 according to another exemplary embodiment of the invention will be described briefly with reference to FIGS. 4 and 5 and FIGS. 7A to 7D. The method of manufacturing the optical plate 150 according to the exemplary embodiment of the invention shown in FIGS. 4 and 5 will be described while focusing on the difference from the method of manufacturing the optical plate 150 according to the exemplary embodiment shown in FIGS. 2 and 3, in order to avoid redundancy.

In the method of manufacturing the optical plate 150 according to the exemplary embodiment of the invention shown in FIGS. 4 and 5, forming the first optical sheet 151 includes forming the plurality of the first sub-pattern 152A having the first height H1 on the first base 151B, and forming the plurality of the second sub-pattern 152B, which have the second height H2 greater than the first height H1, on the first base 151B.

The first and second sub-patterns 152A and 152B may be formed through the extrusion scheme or the soft molding scheme. When the first and second sub-patterns 152A and 152B are formed through the extrusion scheme or the soft molding scheme, the first and second sub-patterns 152A and 152B may be substantially simultaneously formed through a single process.

The plurality of the first sub-pattern 152A may be formed through the extrusion scheme or the soft molding scheme, and the plurality of the second sub-pattern 152B may be formed on the first sub-pattern 152A through a photolithography scheme or a sputtering scheme using a mask.

In order to form the plurality of the second sub-pattern 152B through the photolithography scheme, photoresist (not shown) is coated on the first optical sheet 151 having the plurality of the first sub-pattern 152A. A mask (not shown) having a shape corresponding to the size, the shape, and the position of the plurality of the second sub-pattern 152B to be formed is prepared. Thereafter, the photoresist is exposed and developed by using the mask. Thereafter, the photoresist is etched such that a portion of the photoresist is removed, thereby forming the plurality of the second sub-pattern 152B.

In order to form the plurality of the second sub-pattern 152B through the sputtering scheme using the mask, the first optical sheet 151 having the plurality of the first sub-pattern 152A is prepared. A mask (not shown) having a shape corresponding to the size, the shape, and the position of the plurality of the second sub-pattern 152B to be formed is prepared. Thereafter, a material to be sputtered is placed on a target of a sputtering device. Power or heat energy is applied to the material, so that the plurality of the second sub-pattern 152B is formed on the first optical sheet 151 having the plurality of the first sub-pattern 152A by using the mask.

The separate first optical sheet 151 formed through the above method is bonded with the second optical sheet 153 formed on the rear surface 153R thereof with the reflective layer 155, thereby forming the optical plate 150 according to another exemplary embodiment of the invention.

The optical plate 150 according to the exemplary embodiment shown in FIG. 6 may be formed through the manufacturing method the same as that of the optical plate according to the exemplary embodiment shown in FIGS. 4 and 5.

As described above, the method of manufacturing the optical plate according to the exemplary embodiments of the invention shown in FIGS. 2-6 has a simple manufacturing process, so that the optical plate can be easily manufactured at lower cost.

Although the exemplary embodiments of the invention have been described, it is understood that the invention should not be limited to these exemplary embodiments but various changes and modifications can be made by one ordinary skilled in the art within the spirit and scope of the invention as hereinafter claimed. In one exemplary embodiment, although the separate first optical sheet bonded with the second optical sheet according to one embodiment of the invention is disclosed, another optical sheet having a predetermined pattern can be additionally bonded. Accordingly, the technical scope of the invention is not limited to the above detailed description, but should be determined based on accompanying claims.

What is claimed is:

1. An optical plate comprising:
a first optical sheet comprising first patterns protruding from a first front surface, at least a portion of the first patterns including a top surface substantially parallel to the first front surface;
a reflective layer disposed facing the top surface; and
a second optical sheet including a rear surface making contact with the reflective layer.

2. The optical plate of claim 1, wherein each first pattern is a prism mountain including the top surface substantially parallel to the first front surface.

3. The optical plate of claim 2, wherein the prism mountain extends in a first direction.

4. The optical plate of claim 1, wherein
the first patterns comprise first sub-patterns having a first height from the first front surface, and second sub-patterns having a second height greater than the first height from the first front surface, and
the reflective layer is provided on the second sub-patterns.

5. The optical plate of claim 4, wherein
each second sub-pattern has one of a cylinder shape, a poly-prism shape, an elliptic cylinder shape, a truncated conical shape, and a truncated poly-pyramidal shape, and
a top surface of each second sub-pattern is substantially parallel to the first front surface.

6. The optical plate of claim 5, wherein each first sub-pattern is a prism mountain extending in one direction.

7. The optical plate of claim 5, wherein each first sub-pattern has one of a pyramid pattern, a lenticular pattern, and a semi-oval sphere pattern.

8. The optical plate of claim 1, wherein the second optical sheet comprises second patterns protruding from a second front surface.

9. The optical plate of claim 8, wherein each second pattern is a prism mountain extending in a second direction crossing a first direction.

10. The optical plate of claim 9, wherein each of the first and second optical sheet has a rectangle shape, and the first and second directions perpendicularly cross each other.

11. The optical plate of claim 1, wherein the reflective layer comprises a metal.

12. The optical plate of claim 1, wherein the reflective layer comprises Titanium Dioxide (TiO₂) or Barium Sulphate (BaSO₄).

13. The optical plate of claim 1, wherein the second optical sheet includes an adhesion layer disposed on the rear surface thereof, the adhesion layer contacting the first optical sheet to adhere to the second optical sheet with the first optical sheet.

14. A method of manufacturing an optical plate, the method comprising:
forming a first optical sheet including first patterns protruding from a first front surface;
forming a second optical sheet;
forming a reflective layer on a portion of the second optical sheet;
forming an adhesion layer on the second optical sheet; and
bonding the first optical sheet to the second optical sheet such that at least a portion of the first patterns makes contact with the reflective layer.

15. The method of claim 14, wherein the forming a reflective layer comprises printing a reflective material on a portion of a rear surface of the second optical sheet.

16. The method of claim 14, wherein the first patterns are formed through an extrusion scheme or a soft molding scheme.

17. The method of claim 14, wherein the forming a first optical sheet comprises:
forming first sub-patterns having a first height on a base sheet; and
forming second sub-patterns having a second height greater than the first height on the base sheet.

18. The method of claim 17, wherein the first and second sub-patterns are formed through a single process.

19. The method of claim 17, wherein the second sub-patterns are formed through a photolithography process.

20. The method of claim 17, wherein the second sub-patterns are formed on the first sub-patterns through a sputtering process using a mask.
